(19) United States
(12) Patent Application Publication
(10) Pub. No.: US 2003/0135338 A1
(43) Pub. Date: Jul. 17, 2003

(54) Real-time energy monitoring system

(76) Inventors: Kenneth R. Knaus, Sunnyvale, CA (US); Gerald J. Gleason, Los Altos, CA (US); Paul G. Russell, Campbell, CA (US)

Correspondence Address: HEWLETT-PACKARD COMPANY, Intellectual Property Administration, P.O. Box 272400, Fort Collins, CO, 80527-2400, US

(21) Appl. No.: 10/042,313

(22) Filed: Jan. 11, 2002

(51) Int. Cl. G01R 21/00

(52) U.S. Cl. 702/61

(57) ABSTRACT

A real-time energy monitoring system which monitors the energy consumption of a residence or business. The system includes a device located in an interface module for sensing the instantaneous value of the energy being measured by the utility meter. The system also includes a photo-transistor which receives the reflected light from a black stripe on the rotating aluminum disk. The photo-transistor produces a signal corresponding to the instantaneous energy usage. A transmitter is coupled to the phototransistor for encoding and transmitting the digital signal. A receiver receives and decodes the transmitted digital signal. A display unit displays the real-time energy consumption data to a user.

### FIELD OF THE INVENTION

This invention relates generally to an energy monitoring system, and more particularly to a system for real-time monitoring of energy consumption over a fixed period and presenting energy consumption information to the user via a display device.

### BACKGROUND OF THE INVENTION

Most people are familiar with the power company's utility meters outside their homes, businesses or apartments. The vast majority of these meters have electromechanical meters which are read by utility company service people on a monthly basis. These readings are used to compute the monthly electricity bills.

A utility meter (which measures energy usage in kilowatts-hours (KWH)) is installed by the local power company on the outside of the building or home. Normally, the utility meter has a glass enclosure and several dials on flat panel encased inside the glass enclosure. The utility company supplies current to a house or business (for example) via the utility meter. The current passes through a coil which energizes a small motor in the meter. The motor armature is a flat aluminum disk with a black stripe, which is visible from the front of the meter. The rate of rotation of the aluminum disk is proportional to the amount of energy that is flowing into the house or business.

The rotating disk drives a series of gears, in a mechanism for the pointer needles or the scales that are labeled from zero to nine. There are usually 5 separate dials, and they act similar to an odometer for a car. The dials indicate the accumulated energy consumed.

Typically, a utility employee visually reads the meter and records the numbers displayed on the dials once a month. The previous reading is subtracted from the present month's reading to determine the exact amount of energy used during the billing period. The user is typically charged the rate of $0.10 to $0.30/kilowatt hour used.

Given the increased cost of energy, coupled with substantial cost increases in electrical utilization, it is axiomatic that energy conservation is essential. However, the effects of conservation cannot be determined until the end of the billing cycle, which is typically 4 or 5 weeks in the future.

There is a need to provide the user with a system to monitor (and therefore better control) electrical consumption in real time, thereby minimizing the surprise of receiving a larger than expected bill from the utility company. This invention allows the user to monitor in real-time the electricity consumption and to adjust conservation efforts according to use.

U.S. Pat. No. 6,226,600 provides a system, which monitors the real time energy consumption and displays it to the user. The system uses an electrical current and voltage measurement along with a power line carrier transmission interface to transmit a signal over existing power circuits within the residence or home. However, this requires a costly professional installation and power disruption while the system is being installed.

Therefore, we need a low cost system which provides a real-time energy monitoring system that uses a non-intrusive method of sensing and transmitting a signal from the meter to the home or business, and that can be installed by a non-professional consumer/user.

### SUMMARY OF THE INVENTION

The invention is a real-time energy monitoring system, which monitors the energy consumption of a residence or business. The system includes the existing utility meter coupled to main power connection that measures the amount of energy over a period of time. The system includes a receiver which receives and decodes the transmitted digital signal.

Furthermore, the system includes a display unit, which displays the real-time energy consumption data to the user. The display unit further comprises the following features: a power supply for powering the display unit, and a receiver circuit for receiving the decoded digital signal, a microprocessor circuit for processing information received by the display unit, at least one memory device for the storage of data, a liquid crystal or LED display, a plurality of user input buttons which allows the user to configure the display unit.

The transmitter circuit is inside a module that is physically attached to the top, bottom or front of the utility meter in such a way as to not impair the utility meter from being read.

In another respect, the invention is a real-time energy monitoring system which monitors the energy consumption of an existing home or business. The method includes an utility meter coupled to main power connection that measures the amount of energy over a period of time. The method comprises a photo-transistor circuit in the transmitter circuit for sensing the instantaneous value of the energy being measured by the utility meter. The method also includes a RF modulator coupled to a radio frequency transmitter to transmit the digital signal. A receiver circuit receives and demodulates the transmitted digital signal. Furthermore, the received signal drives a display unit which displays the real-time energy consumption data to a user.

The photo-transistor circuit includes a light source for shining light on an aluminum rotor disk in the utility meter. The photo-transistor circuit receives the reflected light from the edge of the aluminum armature disk which produces an analog signal, that represents the instantaneous energy value.

In yet another respect, the invention is a method for providing a user real-time energy consumption information displayed on an LCD display unit. The method comprises the steps of: generating a signal which represents the instantaneous energy value, transmitting the digitized signal over a radio link, processing the received signal to convert the received signal to energy measurement information, and displaying the energy measurement information on a display unit.

The method further comprises the steps of: monitoring the instantaneous energy output from a utility meter, and receiving the transmitted signal. The step of generating includes a photo-transistor circuit for sensing the instantaneous energy, and the step of transmitting further comprises the step of the transmitting the digitized signal either by infrared, radio, or wire; and the receiver receives and decodes the transmitted signal.

In comparison to known prior art, certain embodiments of the invention are capable of achieving certain aspects, including some or all of the following: (1) providing a low cost non-contact real-time measurement of electric energy consumption and minimizing the angst of waiting for the next utility bill; (2) allowing users to take remedial measures to reduce energy consumption and instantly see the effects of those measures; and (3) providing users with long term trend analysis of their energy consumption and costs. Those skilled in the art will appreciate these and other advantages and benefits of various embodiments of the invention upon reading the following detailed description of a preferred embodiment with reference to the below-listed drawings.

### BRIEF DESCRIPTION OF THE DRAWINGS

A more complete understanding of the invention and its advantages will be apparent from the following detailed description taken in conjunction with the accompanying drawings, wherein examples of the invention are shown and wherein:

FIG. 1 is a block diagram of a first embodiment of the real-time home monitoring system according to an embodiment of the invention;

FIG. 2 is a block diagram of a second embodiment of the real-time home energy monitoring system, according to an embodiment of the invention;

FIG. 3 is a schematic diagram of a outside electric power meter, according to an embodiment of the invention;

FIG. 4 is a schematic diagram of a display unit, according to an embodiment of the invention;

FIG. 5 is a logic diagram for the display unit; and

FIG. 6 is a flow chart for a method of providing real-time energy consumption information, according to an embodiment of the invention.

### DETAILED DESCRIPTION OF A PREFERRED EMBODIMENT

In the following detailed description, numerous specific details are set forth in order to provide a thorough understanding of the present invention. However, it will be apparent to one of ordinary skill in the art that these specific details need not be used to practice the present invention. In other instances, well known structures, interfaces, and processes have not been shown in detail in order not to unnecessarily obscure the present invention.

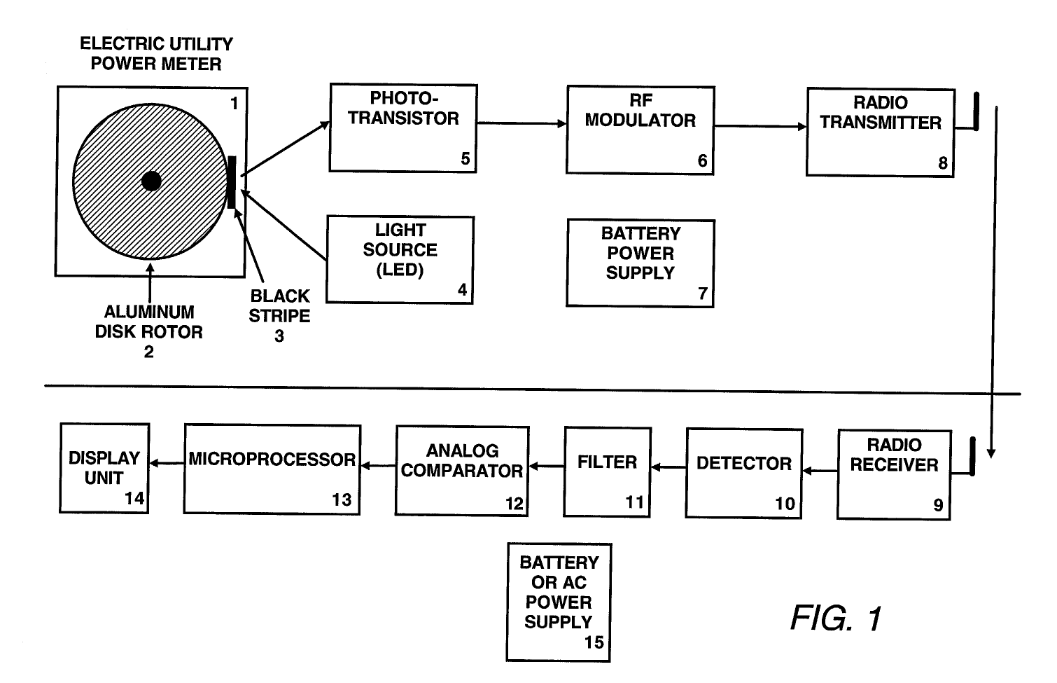

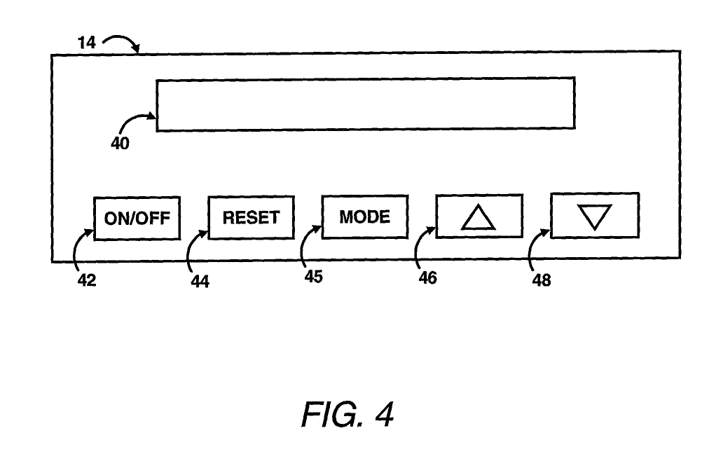

A real-time home energy monitoring system where a signal representing the instantaneous energy value output from a utility meter 1 is digitized and transmitted to a receiver circuit is illustrated in FIG. 1. The receiver circuit is typically located within a display unit (which is discussed in more detail with regards to FIG. 4) 14 which processes and displays real-time power usage information. The home energy information system includes a transmitter circuit and a receiver circuit. The transmitter circuit includes an LED light source 4, photo-transistor 5, RF modulator 6, battery power supply 7 and radio transmitter 8. The transmitter circuit is preferably attached to the utility meter 1. The receiver circuit includes a radio receiver 9, detector 10, filter 11, analog comparator 12, microprocessor 13 and display unit 14.

The utility meter 1 measures energy from the utility company and outputs it to a home or business in accordance with the required usage. In the preferred embodiment of the invention, the utility meter 1 includes an aluminum disk rotor 2 with a black stripe 3. The aluminum disk rotor 2 rotates in accordance with the amount of energy that is being consumed by the home or business.

The real-time home energy monitoring system operates by sensing and counting the rotations of the aluminum disk rotor 2 in the utility meter 1. This is accomplished by using the light source 4 to illuminate the aluminum disk rotor 2 in order to determine the rate of rotation of the black stripe 3. The photo-transistor 5 produces a pulse signal whose period corresponds to the rate of rotation of the black stripe 3 on the aluminum disk rotor 2. The rate of rotation corresponds to the instantaneous energy being measured by the utility meter 1. The signal is output from the photo-transistor S to an RF modulator 6. The RF modulator 6 is of a type well known in the art. The RF modulator 6 modulates the signal and outputs it to the radio transmitter 8 which transmits it to the radio receiver 9. The radio transmitter 8 transmits the signal in a known fashion. The battery power supply 7 supplies power to the transmitter unit. However, one of ordinary skill in the art can recognize that other sources of power can be employed.

The radio receiver 9 receives the transmitted signal and outputs it to the detector 10. The detector 10 demodulates the received signal in a conventional fashion. The filter 11 receives detected signal and filters the signal in a known fashion. The analog comparator 12 receives the filtered signal and the analog comparator converts the filtered analog signal to a digital signal. The signal is applied to a microprocessor 13 which processes the signal and generates the instantaneous energy usage information or other types of information which is displayed on the display unit 14. The display is a part of a larger display unit (as discussed with FIG. 4).

The display unit 14 illustrates various types of information regarding the energy consumption (e.g., energy used to date, average daily cost, running cost and the like). The receiver unit is powered by a battery or AC power supply 15.

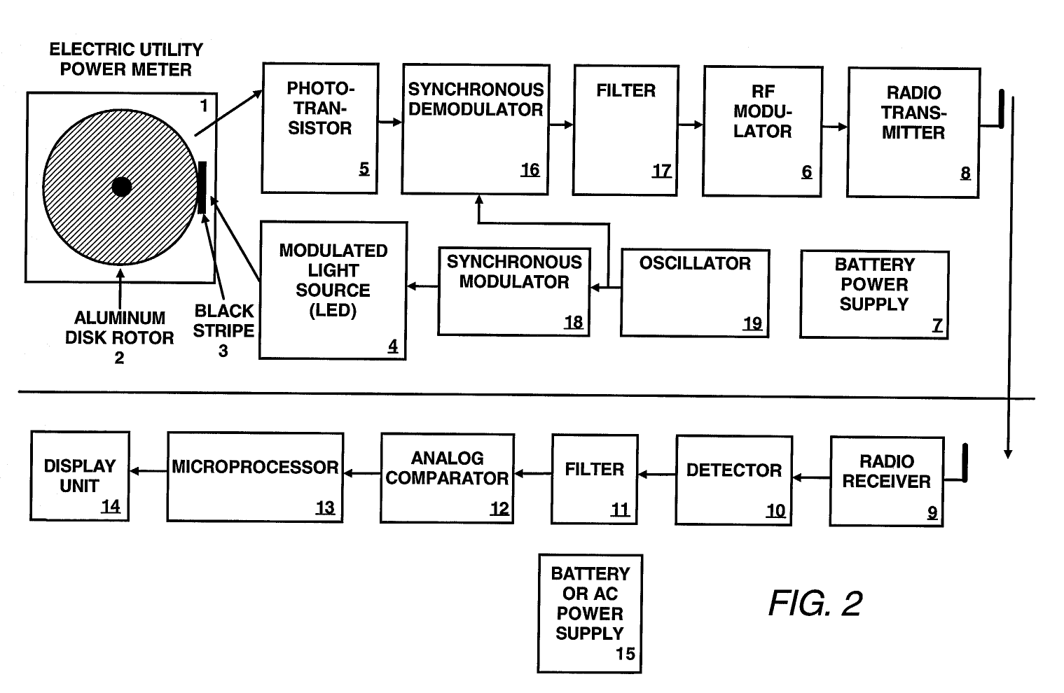

FIG. 2 illustrates a second embodiment of the real-time home energy monitoring system. The system also includes a transmitter circuit and a receiver circuit. The transmitter circuit comprises an oscillator 19, a synchronous modulator 18, a modulated light source 4, photo-transistor circuit 5, synchronous demodulator 16, filter 17, an RF modulator 6, battery power supply 7, radio transmitter 8. The receiver circuit comprises a radio receiver 9, detector 10, filter 11, analog comparator 12, microprocessor 13, display unit 14 and a battery or AC power supply 15.

The utility meter 1 measures energy from the utility company and outputs it to a home or business in accordance with the required usage. In the preferred embodiment of the invention, the utility meter 1 is analog in nature. The utility meter 1 includes an aluminum disk rotor 2 with a black stripe 3. The aluminum disk rotor 2 rotates in accordance with the amount of energy that is being supplied to the home or business.

The transmitter circuit operates by using the modulated light source 4 and a phototransistor 5 to sense the change in the optical contrast of the reflected light as the black stripe 3 rotates on the aluminum disk rotor 2 inside the utility meter 1. The oscillator 19 is set to operate at a predetermined frequency. The oscillator 19 is connected to the synchronous modulator 18 that produces a modulated signal having the oscillator frequency. The modulated signal is then applied to the modulated light source 4. The modulated light source 4 is designed to generate illumination at the oscillator frequency. Therefore, the modulated light source illuminates the aluminum disk rotor 2 at discrete intervals in accordance with the modulated signal.

The photo-transistor 5 receives the reflected light from the aluminum disk rotor 2. The photo-transistor 5 produces a pulse signal whose period corresponds to the rate of rotation of the black stripe 3 on the aluminum rotor disk 2. The rate of rotation corresponds to the instantaneous energy being output from the utility meter 1. The output of the phototransistor 5 is the synchronous demodulator 16. The synchronous demodulator 16 removes noise or extraneous signals from the optical detection process. This is a well-known technique in the art. The synchronous demodulated signal is filtered by the filter 17 and modulated by the RF modulator 6. The radio transmitter 8 then transmits the modulated signal to the receiver circuit.

The receiver circuit operates in a manner substantially similar to that of the receiver circuit described with regards to FIG. 1.

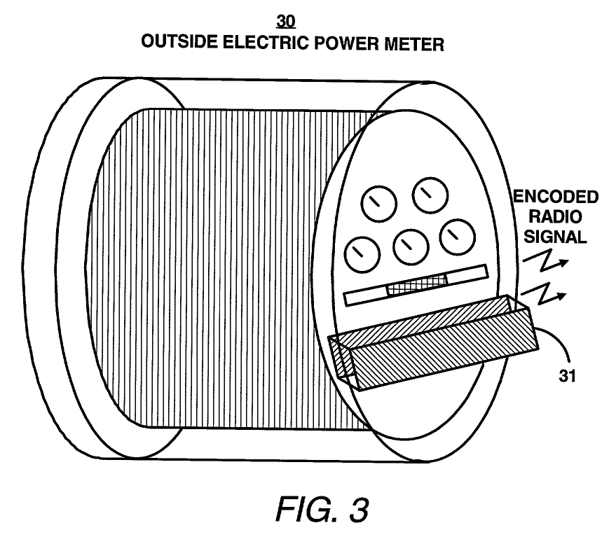

FIG. 3 is a schematic diagram illustrating the outside electric power meter 30, according to an embodiment of the invention. The real time energy monitoring in-system 31 is attached to the glass cover of the utility meter 1, in such a manner as to not block or prevent the dials on the face of the meter from being seen. One of ordinary skill in the art can readily appreciate the fact that FIG. 3 is shown for illustrative reasons only and the invention can be practiced by numerous different configurations. The real time interface monitoring system 31 is placed so that it can sense the motion of an aluminum disk rotor 2, but not in such a manner as to block the view dials on the utility meter 1. However, one of ordinary skill in the art can envision other locations of the transmitter circuit. For example, the transmitter circuit could be attached to the top or bottom of the utility meter 1 in such a manner that would allow a power company employee to read the meter.

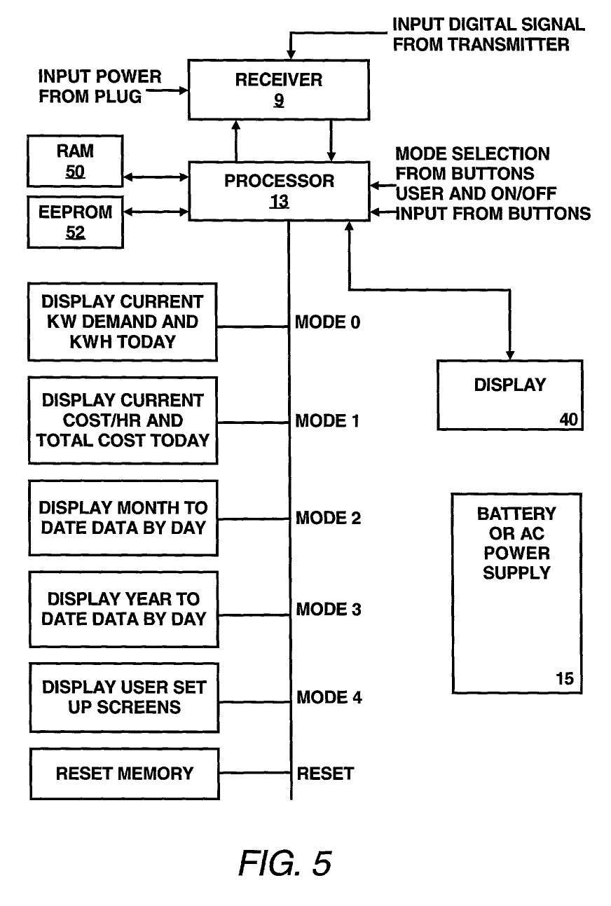

FIG. 4 is a schematic diagram of an exemplary display unit 14. The display unit 14 includes an LCD display 40, an ON/OFF switch 42, a RESET button 44, a MODE button 45, and a UP and DOWN, user input buttons 46 and 48. The display unit 14 also includes a plug (not shown) to connect to an outlet or battery pack to supply power to the internal circuitry (not shown). A port (not shown) could also connect the display unit 14 to a personal computer (PC) in a known manner that would allow communications of data between the devices. As stated above, the display unit 14 also includes the receiver circuit and the microprocessor 13. The microprocessor 13 (which will be discussed further in reference to FIG. 5) is connected to the LCD display 40 in the display unit 14. Preferably, the LCD display 40 and the buttons on the face of the display unit 14 are illuminated. The buttons allow the user to input setup data and control the mode of the LCD display 40. The operation of the display unit 14 will be discussed in further detail with regards to FIG. 5.

FIG. 5 is a logic diagram of an exemplary display unit 14. The diagram illustrates the radio receiver 9, microprocessor 13, Random Access Memory (RAM) 50, and Electrical Erasable Programmable Read Only Program (EEPROM) 52 and the various modes of operation for the display unit 40. The RAM 50 and EEPROM 52 are preferably located in the display 14, however, one of ordinary skill can envision a situation where they are located in the microprocessor 13. The microprocessor 13 controls the operation of the display unit 40. Preferably, a program stored in the EEPROM 52 controls the operation of the microprocessor 13. The program stored in the EEPROM 52 is easily manufactured to incorporate updated enhancements.

The RAM 50 is used for temporary storage of data. The energy signal is received by the radio receiver 9 and passed on to the microprocessor 13 as shown in FIGS. 1 and 2. An updated received signal is preferably received approximately once per second and this signal is continuously sent to the microprocessor 13. The receiver circuit receives input power from an AC or battery operated power supply 15. The microprocessor 13 receives input from at least two sources. First, the mode selection button 45 and secondly the ON/OFF switch 42, RESET 44 and user input buttons 46 and 48 are on the face of the display unit 14.

As part of the setup routine, the user can set the current time and date, set the billing cycle date and input the cost per Kilowatt Hour (KWH) charged by the utility company. Preferably, the display unit 40 can accept utility rates that vary with time of day, month, year or total usage for the month. From this information, the microprocessor 13 calculates the current electrical energy consumed in kilowatts. This value then can be displayed on the LCD screen 40 and can be updated approximately every second. The microprocessor 13 then calculates the current cost of electrical usage per hour by multiplying the KWH energy consumption by the then current utility rate per KWH to derive a current consumption cost in dollars per hour. One of ordinary skill in the art can recognize that other models can be put in place of other currency. The energy consumed and its corresponding cost is displayed in the LCD screen 40.

This value is saved in the EEPROM 52 as shown in FIG. 5. The value is continually updated and therefore reflects the total KWH usage for that day. This value also can be displayed on the LCD screen 40. At the end of the day, (or predetermined period) the value is saved. The daily totals are saved for historical purposes. Similarly, the microprocessor 13 stores the current dollar cost so far for the day, week or month. This value also can be displayed on the LCD screen 40. At the end of the billing cycle month, the total KWH usage and dollar cost for the month are calculated and stored. These figures should closely resemble the user's utility bill for that particular month. The monthly figures are stored in the EEPROM 52 or can be transmitted to a personal computer (PC) connected to the microprocessor 13 for remote storage.

The microprocessor 13 can manipulate all of the stored data and display the information in various alphanumeric or graphical formats on the LCD screen 40. The user changes the LCD screen 40 through the use of the mode 45 and user input 46, 48 buttons as shown in FIG. 4. The user can select between the various types of displays described above by pressing the mode button 45 a particular number of times. Each time the mode button 45 is pressed a different value is displayed on the LCD screen 40.

The following discussion is an example of various values that can be displayed on LCD screen 40 as shown in FIG. 5. One of ordinary skill can appreciate that the process can be set-up in numerous ways. In the example, when the unit is operating in a default mode (mode 0, the user has not pressed the mode button 55) the LCD screen 40 displays the current KW demand and KWH consumed today. If the user presses the mode button 45, mode 1 is displayed. Mode 1 displays the current cost per hour and the total cost per day. For each subsequent depression of the mode button 45 a different mode is displayed. Mode 2 displays month to date KWH consumption by day. Mode 3 displays year to date KWH consumption by month. Mode 4 displays user set-up screen. The user employs the input buttons 46 and 48 to manually input the billing utility rates and the billing cycle date. The user can manually input various billing rates including time of day changes, month of year changes and monthly consumption charges. The RESET button 44 allows the user to delete the accumulated information stored in the RAM 50. The RESET button 44 resets billing information to default information entered on set-up or resets the current mode values to zero.

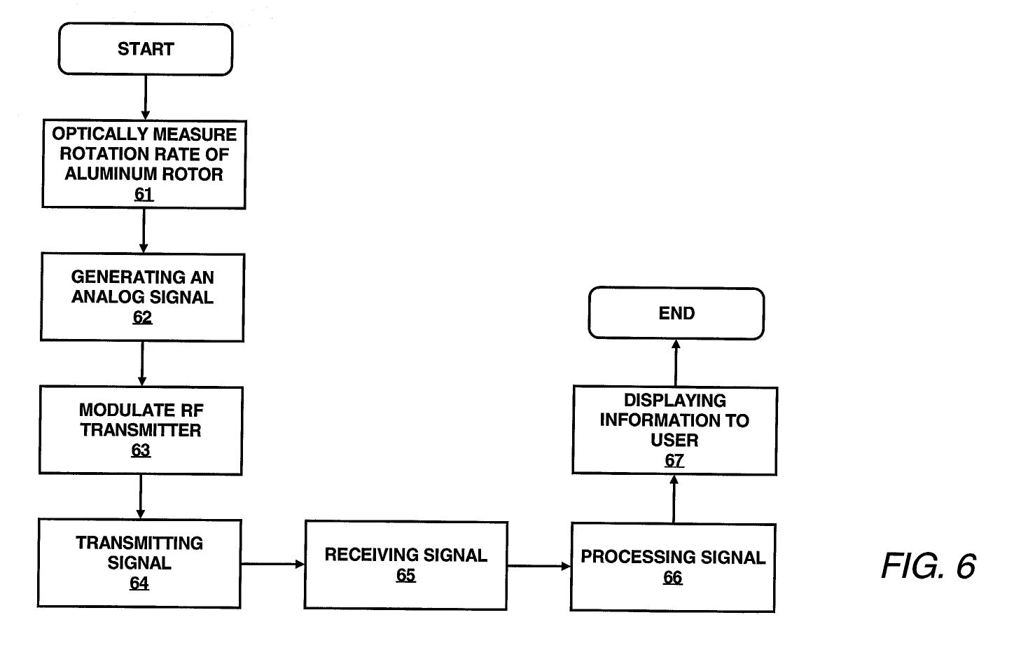

FIG. 6 is a flowchart illustrating the main steps of the preferred embodiment of the invention. In Step 61, the photo-detector circuit monitors the energy measured by the utility meter 1 by sensing and counting the rotations of the aluminum disk rotor in the utility meter 1.

In step 62 the output of the photo detector represents the rate of rotation of the aluminum disk rotor in the utility meter.

In step 63, the analog signal is modulates the RF carrier in the transmitter, which is proportional to the energy consumed. This signal may be encrypted prior to this stage to ensure personal information security.

In step 64, the transmitter 8 transmits the digital signal over a radio link.

In step 65, the radio receiver 9 receives the transmitted signal. The receiver circuit is preferably located inside the home or business. More specifically, the receiver circuit is preferably located within the display unit 14. The receiver circuit includes a detector 10 and an analog comparator circuit 12 which receives and decodes the transmitted signal.

In step 66, the microprocessor 13, located preferably in the display unit 14, performs predetermined operations on the received signal to produce signals representing specific measurement information.

In step 67, the specific measurement information is display to the user via the display 14.

The foregoing description of a preferred embodiment of the invention has been presented for purposes of illustration and description. It is not intended to be exhaustive or to limit the invention to the precise form disclosed, and modifications and variations are possible in light of the above teachings or may be acquired from practice of the invention. The embodiment was chosen and described in order to explain the principles of the invention and its practical application to enable one skilled in the art to utilize the invention in various embodiments and with various modifications as are suited to the particular use contemplated. It is intended that the scope of the invention be defined by the claims appended hereto, and their equivalents.

What is claimed is:

1. A real-time energy monitoring system operable to monitoring instantaneous energy consumption, the system comprising:
a photo-detector located with a transmitter circuit for producing a signal corresponding to an instantaneous value of energy being measured by a utility meter;
a transmitter coupled to the photo-detector for transmitting the signal corresponding to an instantaneous value of energy; and
a display unit configured to receive and decode the transmitted signal and displays real-time energy consumption data to a user.

2. The system of claim 1, further comprising:
an electric power utility meter having an aluminum disk rotor with a black stripe such that the electric power utility meter is coupled to a power connection and measures the amount of energy used in a predetermined period of time.

3. The system of claim 1, further comprising:
a RF modulator which modulates the signal.

4. The system of claim 1, further comprising:
a light source which illuminates the aluminum disk rotor at a predetermined rate;
an oscillator;
an oscillator coupled to the synchronous modulator coupled for modulating the light signal; and
a synchronous demodulator coupled to the detector and the oscillator for removing noise from the detected signal.

5. The system of claim 1, wherein the display unit further comprises:
a power supply for powering the display unit;
an interface circuit for receiving the decoded digital signal, receiving the input power, and transmitting and receiving information to a peripheral device;

6. The system of claim 5, further comprising:
a microprocessor for processing information received by the display unit;
at least one memory device for the storage of data;
a display; and
a plurality of user input buttons which allows the user to configure the display unit.

7. The system of claim 1, wherein the transmitter circuit is physically attached to utility meter in such a way as to not impair the utility meter from being read.

8. The system of claim 1, wherein the transmitter transmits the signal either by infrared, radio, or wire and the receiver receives and decodes the received signal.

9. The system of claim 6, wherein the display unit is configured to display information carried by the signal.

10. The system of claim 9, wherein the display unit is capable of storing the received data and communicating the received data to a personal computer at predetermined intervals.

11. The system of claim 1, wherein the detector is a photo-transistor device for producing an analog signal corresponding to an instantaneous value of energy being measured by a utility meter.

12. The system of claim 11, wherein the detector further comprises:
a light source emitting light on an aluminum rotor disk in the utility meter, and the photo-transistor device receives the light reflected from the armature disk and produces an analog signal which represents the instantaneous energy value.

13. The system of claim 11, further comprising a RF modulator and radio transmitter for transmitting the signal to the receiver circuit.

14. The system of claim 11, wherein the transmitter circuit is physically attached to the utility meter in such a way as to not impair the utility meter from being read.

15. The system of claim 14, wherein the light source, photo-transistor, RF modulator, radio transmitter are housed inside the interface module.

16. A real-time energy monitoring system operable to monitor the energy consumption, the system comprising:
a utility meter coupled to main power connection and measuring the amount of energy used in a predetermined period of time;
a transmitter circuit comprising:
a photo-detector for detecting the instantaneous energy value consumption and generating a corresponding signal;
a radio transmitter circuit coupled to the detector for encoding and transmitting the digital signal;
a receiver which receives and decodes the transmitted digital signal;
a display unit which displays the real-time energy consumption data to a user comprising:
a power supply for powering the display unit;
a power plug for receiving power from an AC wall unit;
a processor circuit for processing information received by the display unit;
at least one memory device for the storage of data;
a liquid crystal display;
a plurality of user input buttons which allows the user to configure the display unit; and
wherein the radio transmitter circuit transmits the digital signal either by infrared, radio or wire and the receiver performs the inverse operation on the received signal;
wherein the transmitter circuit is physically attached to the utility meter in such a way as to not impair the utility meter from being read;
wherein the display unit is capable of translating the received digital signal to the liquid crystal display unit for viewing by the user.

17. The system of claim of claim 16 further comprises:
an oscillator;
a synchronous modulator coupled to the light source; and
a synchronous demodulator coupled to the detector and the oscillator which removes noise from detected signal.

18. The system of claim 16, wherein the detector comprises:
a light source for shining light on an aluminum disk rotor in the utility meter;
a photo-transistor device in an interface module for measuring instantaneous value of the current being output from the utility meter such that the photo-transistor device receives the reflected light from the aluminum disk rotor and produces a signal which represents the instantaneous energy value.

19. A method for providing real-time energy consumption information displayed on an LCD display unit comprising the steps of:
detecting an instantaneous energy value representing the instantaneous energy consumption and generating an signal which corresponds to the instantaneous energy value;
modulating and transmitting the signal to a receiver unit;
processing the received signal at the receiver unit to convert the received signal to energy measurement information; and
displaying the energy measurement information on a display unit.

20. The method of claim 19, further comprising the steps of:
monitoring the instantaneous energy output from a utility meter; and
receiving the transmitted signal.

21. The method of claim 18, wherein the step of generating includes a photo-detector device for measuring the instantaneous energy being consumed.
